(19) United States
(12) Patent Application Publication
(10) Pub. No.: US 2014/0217577 A1
(43) Pub. Date: Aug. 7, 2014

(54) Semiconductor Device and Method for Manufacturing a Semiconductor Device

(71) Applicant: INFINEON TECHNOLOGIES AG, Neubiberg (DE)

(72) Inventor: Gunther Mackh, Neumarkt (DE)

(73) Assignee: Infineon Technologies AG, Neubiberg (DE)

(21) Appl. No.: 13/758,790

(22) Filed: Feb. 4, 2013

(51) Int. Cl. H01L 21/78; H01L 23/52

(52) U.S. Cl. CPC H01L 21/78; H01L 23/52
USPC 257/734; 438/463

(57) ABSTRACT

A device includes a semiconductor chip including a first main face and a second main face, the second main face being the backside of the semiconductor chip. The second main face includes a first region and a second region, the second region being a peripheral region of the second main face. The device further includes a dielectric material arranged over the second region and an electrically conductive material arranged over the first region.

### TECHNICAL FIELD

This invention relates to semiconductor devices and methods for manufacturing semiconductor devices. In particular, the methods may include a laser dicing process.

### BACKGROUND

Semiconductor devices may include a metallization on their backsides. During a production of semiconductor devices laser radiation may be used for separating semiconductor material. In this connection, laser dicing processes may be employed. Semiconductor devices and methods for manufacturing semiconductor devices constantly have to be improved. In particular, it may be desirable to provide a cost efficient method for manufacturing the semiconductor devices and to improve the quality of the manufactured semiconductor devices.

### BRIEF DESCRIPTION OF THE DRAWINGS

The accompanying drawings are included to provide a further understanding of aspects and are incorporated in and constitute a part of this specification. The drawings illustrate aspects and together with the description serve to explain principles of aspects. Other aspects and many of the intended advantages of aspects will be readily appreciated as they become better understood by reference to the following detailed description. The elements of the drawings are not necessarily to scale relative to each other. Like reference numerals may designate corresponding similar parts.

FIG. 1 is a schematically illustrates a cross-sectional view of a device 100 in accordance with the disclosure;

FIGS. 2A to 2C schematically illustrate a cross-sectional view of a method in accordance with the disclosure;

FIGS. 3A to 3I schematically illustrate a cross-sectional view of a method for manufacturing a device 300 in accordance with the disclosure;

FIGS. 4A to 4E schematically illustrate a cross-sectional view of a method for manufacturing a device 400 in accordance with the disclosure;

FIGS. 5A to 5E schematically illustrate a cross-sectional view of a method for manufacturing a device 500 in accordance with the disclosure;

FIG. 6 schematically illustrates a cross-sectional view of a device 600 in accordance with the disclosure; and

FIG. 7 schematically illustrates a cross-sectional view of a device 700 in accordance with the disclosure.

### DETAILED DESCRIPTION OF ILLUSTRATIVE EMBODIMENTS

In the following detailed description, reference is made to the accompanying drawings, which form a part thereof, and in which is shown by way of illustration specific aspects in which the invention may be practiced. In this regard, directional terminology, such as “top,” “bottom,” “front,” “back,” etc., may be used with reference to the orientation of the figures being described. Since components of described devices may be positioned in a number of different orientations, the directional terminology may be used for purposes of illustration and is in no way limiting. It is understood that other aspects may be utilized and structural or logical changes may be made without departing from the scope of the present invention. The following detailed description, therefore, is not to be taken in a limiting sense, and the scope of the present invention is defined by the appended claims.

It is understood that the features of the various exemplary aspects described herein may be combined with each other, unless specifically noted otherwise.

As employed in this specification, the terms “coupled” and/or “electrically coupled” are not meant to mean that the elements must be directly coupled together. Intervening elements may be provided between the “coupled” or “electrically coupled” elements.

The devices described herein may include one or more semiconductor chips (or dies). The semiconductor chips may be of arbitrary type, may be manufactured by different technologies and may, e.g., include integrated electrical, electro-optical or electro-mechanical circuits and/or passives. The semiconductor chips may, for example, be configured as power semiconductor chips. The semiconductor chips may include control circuits, microprocessors or microelectromechanical components. Furthermore, the devices described herein may include logic integrated circuits to control the integrated circuits of other semiconductor chips, for example the integrated circuits of power semiconductor chips. The semiconductor chips need not be manufactured from specific semiconductor material, for example Si, SiC, SiGe, GaAs, and, furthermore, may contain inorganic and/or organic materials that are not semiconductors, such as for example insulators, plastics or metals. The devices and semiconductor chips included therein may be manufactured from a semiconductor wafer.

In particular, the semiconductor chips may have a vertical structure, i.e., the semiconductor chips may be manufactured such that electric currents may flow in a direction perpendicular to the main faces of the semiconductor chips. A semiconductor chip having a vertical structure may have electrodes on its two main faces, i.e., on its top side and bottom side (the bottom side may also be referred to as backside herein).

In particular, the devices described herein may include a power semiconductor chip. Power semiconductor chips may have a vertical structure. The vertical power semiconductor chips may, for example, be configured as power MOSFETs (Metal Oxide Semiconductor Field Effect Transistors), IGBTs (Insulated Gate Bipolar Transistors), JFETs (Junction Gate Field Effect Transistors), power bipolar transistors, or power diodes. For example, the source electrode and gate electrode of a power MOSFET may be located on one main face while the drain electrode of the power MOSFET may be arranged on the other main face.

The terms “frontside” and “backside” of a semiconductor chip or a semiconductor wafer may be used herein. The term “frontside” may particularly relate to a main face of the semiconductor chip that may include microelectronic components and integrated circuits. Semiconductor chips may be manufactured from semiconductor wafers that may serve as a substrate for microelectronic devices to be built in and over the wafer. The integrated circuits may be manufactured by doping, ion implantation, deposition of materials, photolithographic patterning, etc. The manufacturing processes usually may be performed on a specific main surface of the semiconductor wafer which may also be referred to as the “frontside” of the semiconductor wafer. After separating the individual semiconductor chips from the semiconductor wafer, the “frontside” of the semiconductor wafer consequently becomes the “frontside” of the separated semiconductor chips. Contrarily, the term “backside” of a semiconductor chip may refer to a main surface of the semiconductor chip that may be arranged opposite to the frontside of the semiconductor chip. The backside of the semiconductor chip may be free of electronic components, i.e., it may consist of the semiconductor material.

The devices described herein may include an electrically conductive material arranged over the semiconductor chip. The electrically conductive material may particularly have the function of a contact element (or contact electrode) or to provide a coupling to a contact element. That is, the electrically conductive layer may allow an electrical contact to be made with integrated circuits included in the semiconductor chip. In particular, the electrically conductive material may correspond to a backside metallization (or a backside electrode) of a power semiconductor.

The electrically conductive material may include one or more electrically conductive layers that may be applied to the semiconductor material of the semiconductor chips. The electrically conductive layers may be manufactured with any desired geometric shape and/or any desired material composition. The electrically conductive layers may, for example, be in the form of a layer covering an area. Any desired metal, for example Cu, Ni, Sn, Au, Ag, Pt, Pd, and an alloy of one or more of these metals may be used as the material. The electrically conductive layers need not be homogenous or manufactured from just one material. Various compositions and concentrations of the materials included in the electrically conductive layers may be possible.

The electrically conductive layers may be applied over the semiconductor chip. It should be appreciated that any such terms as “formed” or “applied” are meant to cover literally all kinds and techniques of applying layers. In particular, they are meant to cover techniques in which layers may be applied at once as a whole like, for example, laminating techniques as well as techniques in which layers may be deposited in a sequential manner like, for example, sputtering, plating, molding, CVD (Chemical Vapor Deposition), PVD (physical vapor deposition), evaporation, PECVD (plasma enhanced CVD), hybrid physical-chemical vapor deposition (HPCVD), etc. Further processes may include at least one of squeegeeing, printing, dispensing, and spin-coating.

The devices described herein may include a dielectric material arranged over the semiconductor chip. For example, the dielectric layer may include at least one of a nitride, an oxide, and a polymer. The dielectric layer may be applied over the semiconductor material by using one or more of the techniques described in connection with applying the electrically conductive layer. In particular, the dielectric material may include a low temperature oxide. Such low temperature oxide may, e.g., include a TEOS PECVD silicon oxide, i.e., a silicon oxide that may be deposited using a PECVD technique wherein TEOS (Tetraethyl orthosilicate) may be used as a silicon source.

A dicing process may be used for manufacturing the devices described herein. In particular, the dicing process may be used to divide or separate a semiconductor wafer into individual multiple semiconductor chips. In particular, a laser beam (or laser radiation) may be used during the dicing process. For example, a laser stealth dicing technique which is a specific technique using laser dicing may be applied. Laser stealth dicing may allow suppressing cutting waste and may therefore be a suitable process for cutting work pieces that are vulnerable to contamination. Further, it may be a dry process that does not necessarily require cleaning, and may therefore also be suitable for processing sensitive structures such as, e.g., MEMS, that are vulnerable to load. Further benefits which may be achieved by using a stealth dicing technique may be high-speed dicing, superior breakage strength, small kerf, and low running costs.

In laser stealth dicing technology, a laser beam of a wavelength capable of transmitting through the semiconductor wafer may be focused onto a point inside the semiconductor wafer. Here, a wavelength of the laser beam may particularly lie in the infrared range, more particular in the near infrared range, and even more particular in a range from about 1064 nanometers to about 1342 nanometers. Due to a non-linear absorption effect, only localized points inside the semiconductor wafer may be selectively laser-machined, whereby damaging of the front and back surface of the semiconductor wafer may be avoided. The semiconductor wafer may be diced by moving the relative positions of the laser beam and the semiconductor wafer in order to scan the semiconductor wafer according to the desired dicing pattern.

The semiconductor wafer may be diced by applying the semiconductor wafer on a tape, in particular a dicing tape, apply the dicing pattern, in particular a rectangular pattern, to the semiconductor wafer, e.g., according to one or more of the above mentioned techniques, and pull the tape, e.g., in all radial directions. By pulling the tape, the semiconductor wafer may be divided into a plurality of semiconductor chips (or dies).

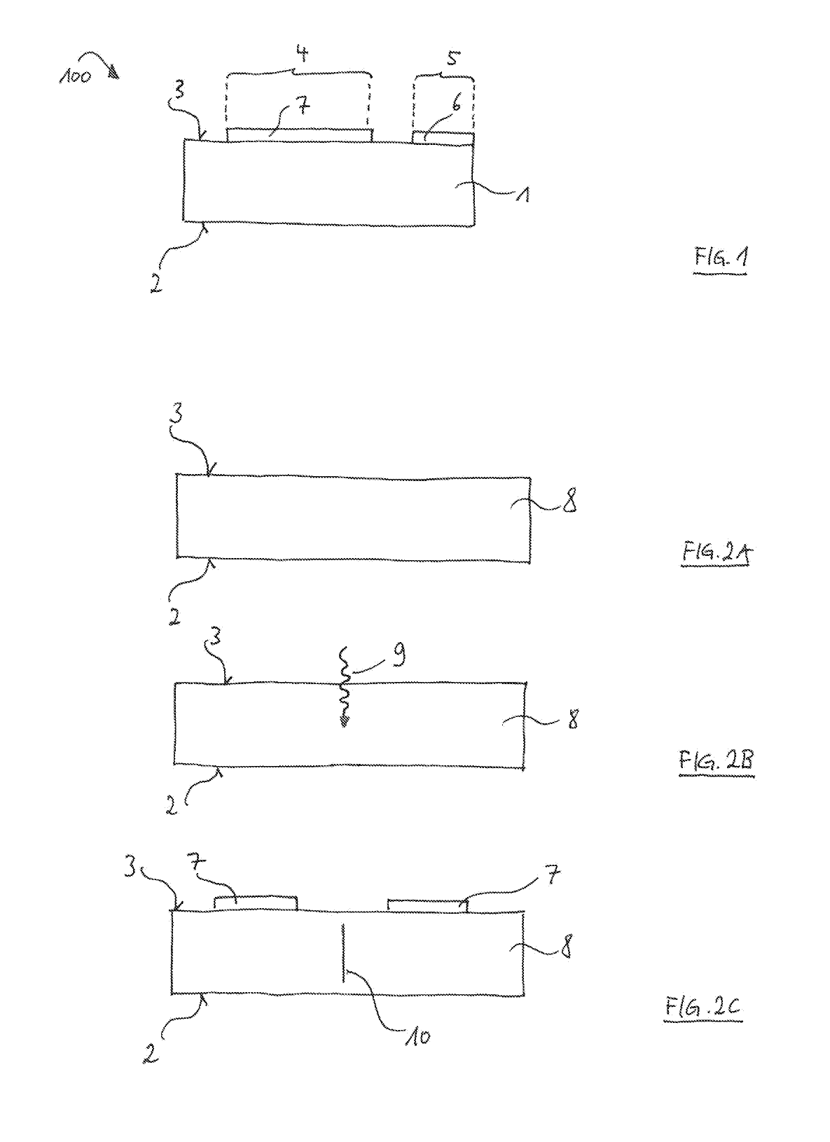

FIG. 1 schematically illustrates a cross-sectional view of a device 100 in accordance with the disclosure. The device 100 includes a semiconductor chip 1 having a first main face 2 and a second main face 3 wherein the second main face 3 is the backside of the semiconductor chip 1. The second main face 3 includes a first region 4 and a second region 5, wherein the second region 5 is a peripheral region of the second main face 3. A dielectric material 6 is arranged over the second region 5, and an electrically conductive material 7 is arranged over the first region 4. It is noted that more detailed devices similar to the device 100 as well as methods for manufacturing such devices are described below.

FIGS. 2A to 2C schematically illustrate a cross-sectional view of a method for manufacturing a device in accordance with the disclosure. In a first step (see FIG. 2A), a semiconductor wafer 8 including a first main face 2 and a second main face 3 is provided. The second main face 3 is the backside of the semiconductor wafer 8. In a second step (see FIG. 2B), the semiconductor wafer 8 is laser diced, for example by using a laser stealth dicing technique. Here, a laser beam (or laser radiation) 9 may be used, the application of which may result in a crack 10 in the semiconductor wafer 8 (see FIG. 2C). In a third step (see FIG. 2C), after laser dicing the semiconductor wafer 8, an electrically conductive material 7 is arranged over the second main face 3. It is understood that the method may include further steps. For example, the semiconductor wafer 8 may be separated into multiple semiconductor devices at the position of the crack 10. The obtained semiconductor devices may be similar to the device 100 of FIG. 1. It is noted that more detailed methods similar to method are described below.

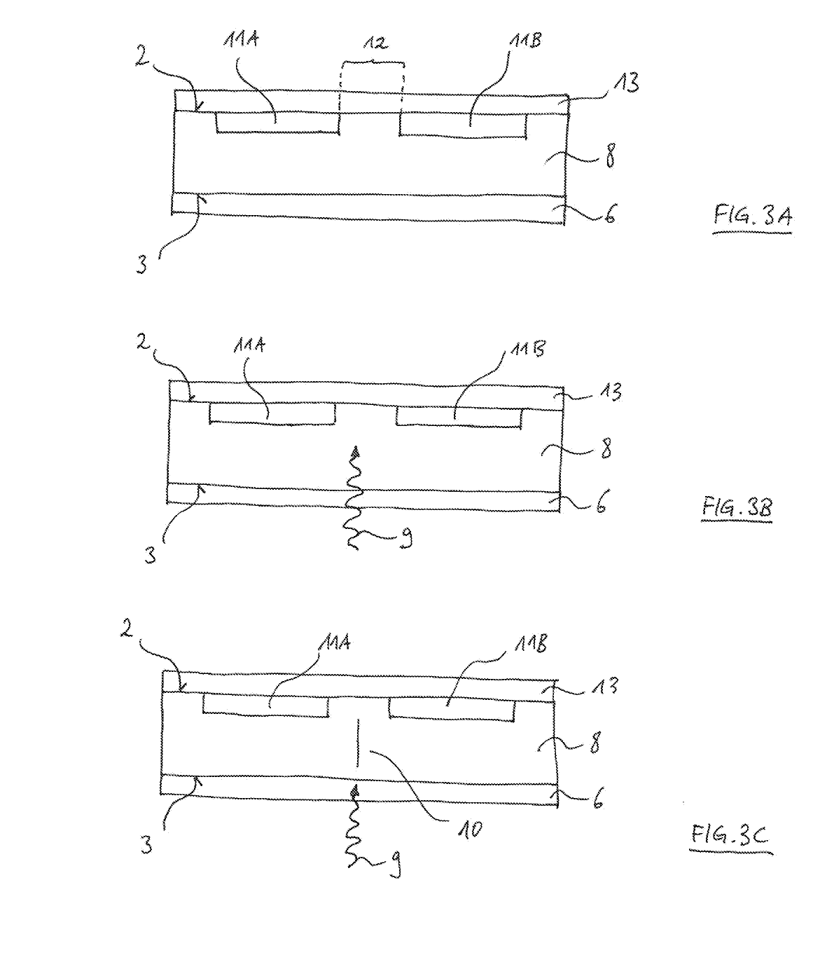

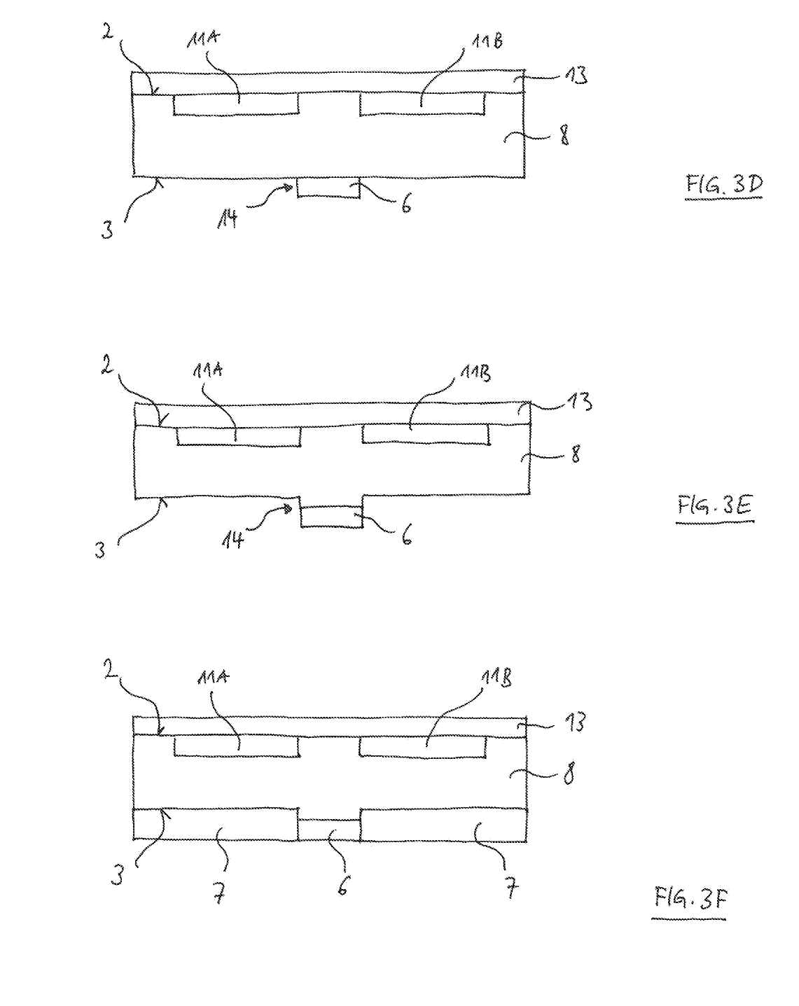

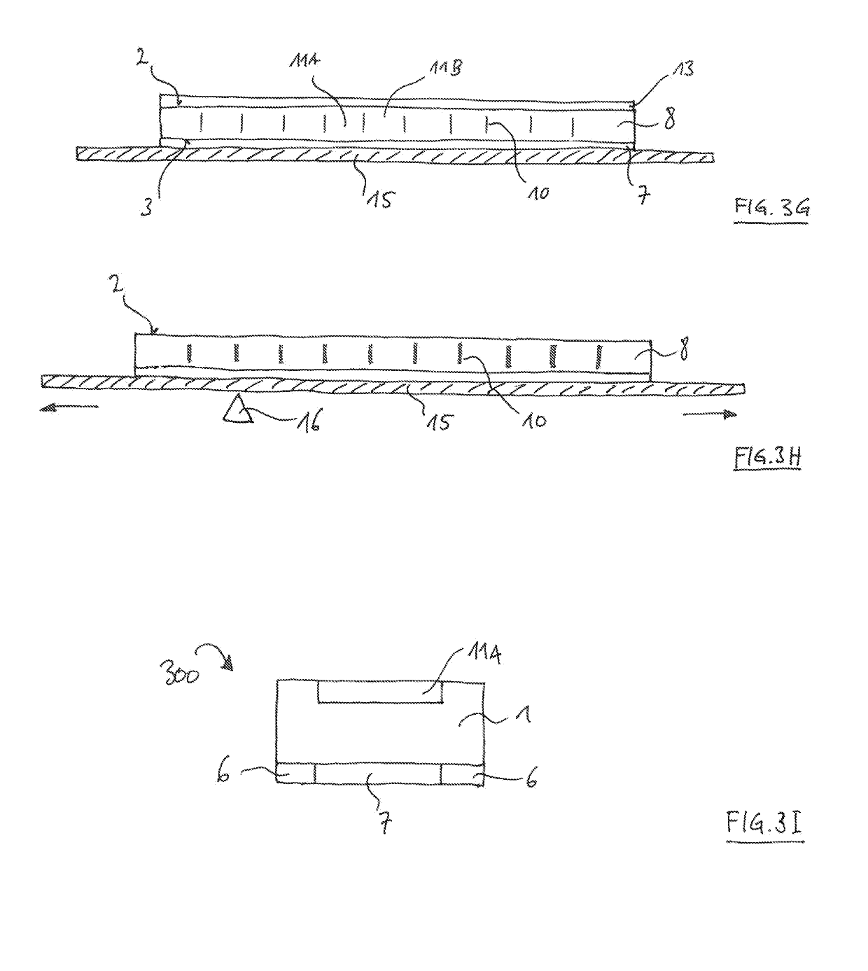

FIGS. 3A to 3I schematically illustrate a method for manufacturing a device 300 in accordance with the disclosure. The device 300 may be seen as an implementation of the device 100 of FIG. 1 and the device manufactured using the method of FIGS. 2A to 2C. In addition, the device 300 may be seen as an implementation of the devices 600 and 700 described below. Details of the device 300 may thus be likewise applied to all other devices in accordance with the disclosure. In addition, the method illustrated in FIGS. 3A to 3I may be seen as an implementation of the method illustrated in FIGS. 2A to 2C. Details of the manufacturing method that are described below may therefore be likewise applied to the method of FIGS. 2A to 2C.

In FIG. 3A, a semiconductor wafer 8 including a first semiconductor chip (or first die) 11A and a second semiconductor chip (or second die) 11B on the frontside 3 of the semiconductor wafer 8 may be provided. Each of the semiconductor chips 11A, 11B may include “used” semiconductor material that may include microelectronic components and integrated circuits as well as “unused” semiconductor material that may be devoid of such electronic structures. It is understood that the semiconductor wafer 8 may include an arbitrary number of further semiconductor chips (not illustrated) adjacent to the first semiconductor chip 11A and the second semiconductor chip 11B. In particular, each of the semiconductor chips 11A, 11B may cover an area smaller than about 10 mm², and more particular smaller than about 5 mm² of the semiconductor wafer 8 frontside 2. The semiconductor chips 11A, 11B may be arranged in an arbitrary geometrical formation or array.

Scribe lines 12 may be arranged between the semiconductor chips 11A, 11B (and between further semiconductor chips that are not illustrated). In particular, the scribe lines 12 may be free of metal that has been used during manufacturing the electronic structures of the semiconductor chips 11A, 11B. The semiconductor chips 11A, 11B may be separated from each other along the scribe lines 12 in a later method step. The scribe line 12 between the semiconductor chips 11A, 11B thus may become a peripheral region of semiconductor chips 11A, 11B after dicing the semiconductor wafer 8 later on. The scribe lines 12 may have a width from about 10 μm (micrometers) to about 30 μm (micrometers), more particular from about 15 μm (micrometers) to about 20 μm (micrometers). The width of the scribe lines 12 may particularly depend on alignment properties and/or a sensitivity of the semiconductor chips 11A, 11B. Selected scribe lines 12 may have a width up to 100 μm (micrometers) and may act as control lines that may be connected to a signal output. For example, the signal output may be configured to provide signals to testing devices.

It is noted that the described method may include additional method steps that have been carried out before the method step illustrated in FIG. 3A. For example, various method steps may have been performed in order to manufacture the first semiconductor chip 11A and the second semiconductor chip 11B, respectively. Each of the first semiconductor chip 11A and the second semiconductor chip 11B may therefore correspond to a back end of line (BEOL) stack. BEOL may be seen as the second portion of IC fabrication where individual devices (transistors, capacitors, resistors, etc.) formed in the semiconductor wafer 8 may be interconnected with wiring in the semiconductor wafer 8. BEOL generally may start when a first layer of metal is deposited on the semiconductor wafer 8. It may include contacts, insulating layers (dielectrics), metal levels, and bonding sites for chip-to-package connections. The frontside of the respective semiconductor chip 11A, 11B may thus include at least one of a doped region, an electrical component, and an integrated circuit. A manufacturing of inner electronic structures of the semiconductor chips 11A and 11B may have been completed such that a passivation layer (not illustrated) may be formed over the frontside 2 of the semiconductor wafer 8. For example, the passivation layer may include silicon nitride. Electrical contacts may be formed on the frontside 2 of the semiconductor chips 11A, 11B, wherein the electrical contacts are configured to provide an electrical connection to electronic structures included in the respective one of the semiconductor chips 11A, 11B.

The semiconductor wafer 8 may have been mounted to a carrier 13 (or vice versa) wherein the frontside 2 of the semiconductor wafer 8 may face the carrier 13. For example, the carrier 13 may be made of at least one of a glass material, and a carbon material. The semiconductor wafer 8 may, e.g., be fixed to the carrier 13 by means of an adhesive layer (not illustrated) or any other suitable technique.

The semiconductor wafer 8 mounted to the carrier 13 may have been thinned to a target thickness in a previous method step. The target thickness may lie in a range from about 30 μm (micrometers) to about 700 μm (micrometers). In this connection, at least one of a grinding technique, a polishing technique, and an (e.g., wet) etching technique may have been used.

A dielectric material 6 may have been deposited on the backside 3 of the semiconductor wafer 8 in a previous method step. For example, the dielectric material 6 may correspond to or may include a layer of a low temperature oxide. In particular, the dielectric material 6 may be chosen to provide a compatibility to temperature limitations of the carrier system including the carrier 13 and an optional adhesive layer. For example, an adhesive layer fixing the semiconductor wafer 8 to the carrier 13 may be only durable to temperatures of up to, e.g., about 250° C., but not above. The properties of the dielectric material 6 may then particularly be chosen such that depositing the dielectric material 6 may be performed at temperatures lower than 250° C. Damage of the adhesive layer may thus be avoided.

In FIG. 3B, the backside 3 of the semiconductor wafer 8 may be scanned by a laser beam (or laser radiation) 9. The wavelength of the laser beam 9 may particularly be chosen that the dielectric material 6 may be (substantially) transparent for the emitted electromagnetic radiation. For example, the wavelength of the laser beam 9 may lie in the infrared range. The laser beam 9 may be focused and applied at predetermined positions in the semiconductor wafer 8. For example, the predetermined positions may correspond to or may include scribe line positions or positions at which a later separation of the semiconductor wafer 8 is intended.

An application of the laser beam 9 may result in a crack 10 in the semiconductor wafer 8 at the position where the laser beam 9 has been applied. In this regard, it is noted that the laser beam 9 may be applied at the predetermined positions one or multiple times at one or multiple depths of the semiconductor wafer 8. The term “depth” may refer to the shortest distance between the backside 3 of the semiconductor wafer 8 and the position in the semiconductor wafer 8 where the laser beam 9 is focused. The number of laser beam applications and the chosen depths may particularly depend on the thickness of the semiconductor wafer 8. In one example, the semiconductor wafer 8 may have a thickness of about 100 μm (micrometers). Here, the semiconductor wafer 8 may be scanned by the laser beam 9 two times, wherein a first crack may be provided at a depth of about 30 μm (micrometers) and a second crack may be provided at a depth of about 70 μm (micrometers) at a predetermined position.

It is noted that applying the laser beam 9 as described in connection with FIG. 3B may change a material structure of the semiconductor wafer 8. In particular, the material structure may be changed at the position where the laser beam 9 has been applied (or focused) as well as at adjacent regions. Before applying the laser beam 9 to the semiconductor wafer 8, the semiconductor material 8 may have a first crystalline structure that may, for example, (substantially) be of monocrystalline type. Applying the laser beam 9 may result in an increased temperature of up to thousands of ° C. in the semiconductor material 8 at the application point of the laser beam 9 and neighboring regions. The semiconductor wafer 8 may at least be partly melted at these regions which may result in a destruction of the monocrystalline structure of the semiconductor wafer 8. After having applied the laser beam 9, the semiconductor wafer 8 may cool down to the previous temperature, thereby forming a second material structure that may be different to the first material structure. For example, the second material structure may (substantially) be of polycrystalline type.

In FIG. 3C, the semiconductor wafer 8 may include a crack 10 resulting from the application of the laser beam 9 described in connection with FIG. 3B. In FIG. 3C, only one exemplary crack 10 is illustrated. However, it is understood that the laser beam 9 may also have been applied such that the semiconductor wafer 8 may have multiple cracks at different depths at the predetermined positions.

The laser beam 9 may further be applied in the vicinity of the dielectric material 6. In particular, the laser beam 9 may be applied to the dielectric material 6 arranged over the positions of the cracks 10. It is noted that an application of the laser beam 9 illustrated in FIG. 3C may differ from an application of the laser beam illustrated in FIG. 3B. For example, the applications may differ in one or more adjustable laser parameters, for example, the wavelength of the laser beam 9, the intensity of the laser beam 9, the time of the laser beam 9 being activated, etc. In FIG. 3C, the laser parameters may be chosen such that an application of the laser beam 9 in the vicinity of the dielectric material 6 may result in a local modification of the material structure or material properties of the dielectric material 6 at or near the positions where the laser beam 9 is applied. For example, a densification of the dielectric material 6 may be provided at the predetermined positions such that the density of the dielectric material 6 arranged over the cracks 10 may be greater than the density of the dielectric material 6 arranged in adjacent regions.

It is noted that an application of the laser beam 9 as described in connection with FIG. 3C may also change a material structure of the semiconductor wafer 8 adjacent to the region of the dielectric layer 6 where the laser beam 9 has been applied. In this regard, comments made in connection with FIG. 3B may also hold true for FIG. 3C.

In FIG. 3D, at least a part of the dielectric material 6 may be removed from the backside 3 of the semiconductor wafer 8. In particular, the dielectric material 6 that has been modified by the laser beam 9 (see FIG. 3C) may partially remain on the backside 3 of the semiconductor wafer 8. For example, a wet etch process, in particular a diluted HF (hydrofluoric acid) wet etch process, may be applied to the backside 3 of the semiconductor wafer 8. The etch rate of the modified (e.g., densified) dielectric material 6 may be smaller than the etch rate of the dielectric material 6 arranged in non-modified areas. The etch time may be chosen such that the non-modified dielectric material 6 may be completely removed. After the wet etch process, the densified dielectric material 6 may remain on the backside 3 of the semiconductor wafer 8. A transition between the areas of the semiconductor wafer 8 with and without the dielectric material 6 arranged on it may have the form of a step 14. Alternatively, an intermediate region may be arranged between these areas, wherein the level of the intermediate region may increase towards the region including the dielectric material 6.

After the wet etch process, a lattice of dielectric material 6 having the form or shape of the scribe lines 12 may remain on the semiconductor wafer 8. That is, the remaining dielectric layer 6 may be arranged at the positions where a later separation of the semiconductor wafer 8 is intended. The form of the lattice may depend on the number and arrangement of the semiconductor chips 11A, 11B.

It is understood that the described structuring of the dielectric material 6 may also be performed by any other suitable technique. For example, the modification of the dielectric material 6 using the laser beam 9 may be omitted. Instead, an etch resistant mask layer (not illustrated) may be arranged over the backside 3 of the semiconductor wafer 8. The mask layer may be formed to cover the scribe lines 12 or regions where the cracks 10 have been provided. After positioning the mask layer, an etching of the dielectric material 6 may be performed such that areas of the dielectric material 6 not covered by the etch resistant mask layer may be removed.

In FIG. 3E, at least one of a silicon wet etching step and a reactive ion etching step may be applied to the semiconductor wafer 8. This additional method step may particularly be used to adjust a height of the step 14. The height of the step 14 may particularly be chosen to correspond to a thickness of an electrically conductive material applied to the backside 3 of the semiconductor wafer 8 later on. For example, the step 14 may have a height from about 1 μm (micrometer) to about 5 μm (micrometers). Due to the additional method step, a level of the semiconductor wafer 8 at the location of the dielectric material 6 may be different from a level of the semiconductor wafer 8 in an adjacent region not covered by the dielectric material 6. It is noted that the method step described in connection with FIG. 3E may be optional. For example, the height of the step 14 may also be adjusted in the method step described in connection with FIG. 3D.

In FIG. 3F, an electrically conductive material 7 may be deposited over the backside 3 of the semiconductor wafer 8 over the areas devoid from the dielectric material 6. For example, a squeegeeing technique may be used to deposit an electrically conductive paste 7. The electrically conductive paste 7 may, e.g., include a metal paste, in particular an Ag nanopaste. For example, the deposited electrically conductive material 7 may have a thickness from about 1 μm (micrometer) to about 5 μm (micrometers). The deposited electrically conductive material 7 may cover at least 80 percent of the overall area of a respective one of the first semiconductor chip 11A and the second semiconductor chip 11B. It is noted that the electrically conductive material 7 may not only include one single layer of one specific material, but may include multiple layers consisting of multiple materials. After depositing the electrically conductive material 7, the surface of the electrically conductive material 7 facing away from the semiconductor wafer 8 and the surface of the dielectric material 6 facing away from the semiconductor wafer 8 may (substantially) be arranged in a common plane. In addition, said surfaces may be flush with each other.

In FIG. 3G, the complete semiconductor wafer 8 is illustrated. The semiconductor wafer 8 may include the semiconductor chips 11A, 11B as well as further semiconductor chips arranged adjacent to the semiconductor chips 11A, 11B. The semiconductor wafer 8 may be applied to an elastic carrier 15 (or vice versa) such that the electrically conductive material 7 faces the elastic carrier 15. For the case of no further material being deposited on the electrically conductive material 7, the electrically conductive material 7 may contact the elastic carrier 15. For example, the elastic carrier 15 may correspond to an elastic foil that may be laminated on the backside 3 of the semiconductor wafer 8. The elastic carrier 15 may have any desired geometric shape or footprint. In particular, the footprint of the elastic carrier 15 may be similar to the footprint of the semiconductor wafer 8.

In FIG. 3H, the carrier 13 may be removed from the frontside 2 of the semiconductor wafer 8. After removing the carrier 13, the elastic carrier 15 may be expanded in a direction indicated by arrows such that the semiconductor chips included in the semiconductor wafer 8 are separated from each other at the locations of the cracks 10. For the case of the footprint of the elastic carrier 15 having a circular form, the elastic carrier 15 may, e.g., be expanded in a radial direction. The elastic carrier 15 may be expanded until a distance between the separated semiconductor chips may have reached a value from about 20 μm (micrometers) to about 40 μm (micrometers). It is understood that there may occur semiconductor chips that are not separated from each other during the expansion of the elastic carrier 15. A separation tool 16 may be used to separate such semiconductors by mechanical force.

Due to the foregoing expansion of the elastic carrier 15 and the (optional) application of the separation tool 16, all semiconductor chips included in the semiconductor wafer 8 may have been separated from each other. In further method steps (not illustrated), the elastic carrier 15 may be removed from the semiconductor wafer 8 and the semiconductor chips included therein may be separated completely from each other.

In FIG. 3I, a separated device 300 obtained after a separation of the semiconductor wafer 8 is illustrated. The dielectric material 6 may be arranged over a peripheral region on the right and the left of the backside of the device 300, respectively.

The specified device 300 and the method for manufacturing the device 300 described in connection with FIGS. 3A to 3I may have the following effects. Such effects may also be observed in connection with any other device or method in accordance with the disclosure.

The described method may provide a possibility of using dicing techniques based on laser radiation, in particular laser stealth dicing techniques, during manufacturing devices having a backside metallization.

Compared to other dicing techniques, using a dicing technique based on laser radiation in accordance with the disclosure may reduce a required width of scribe lines.

Compared to other dicing techniques, using a dicing technique based on laser radiation in accordance with the disclosure may avoid poor chipping quality that may, e.g., occur during mechanical dicing.

By using a manufacturing method in accordance with the disclosure, a patterning of a backside metal required for enabling separation methods like stealth dicing or plasma dicing may be avoided.

By using a manufacturing method in accordance with the disclosure ablation laser processes may be avoided. Ablation laser processes may lead to re-deposition of metal compounds on the chip sidewall and may require wider scribe lines.

For the case of a wafer on carrier (e.g., glass carrier or silicon carrier), a litho alignment between frontside and backside may be difficult after depositing backside metal. This drawback may be avoided by using a method in accordance with the disclosure.

Backside patterning via resist lift off technique may facilitate litho alignment, but may be incompatible with sputter preclean processes (interaction with resist pattern on backside). This drawback may be avoided by using a method in accordance with the disclosure.

Some backside metal stacks, in particular metal stacks starting or including titanium, may require a rough silicon surface. A rough silicon surface may not be compatible with backside stealth dicing, since stealth dicing may require a polished surface. This drawback may be avoided by using a method in accordance with the disclosure.

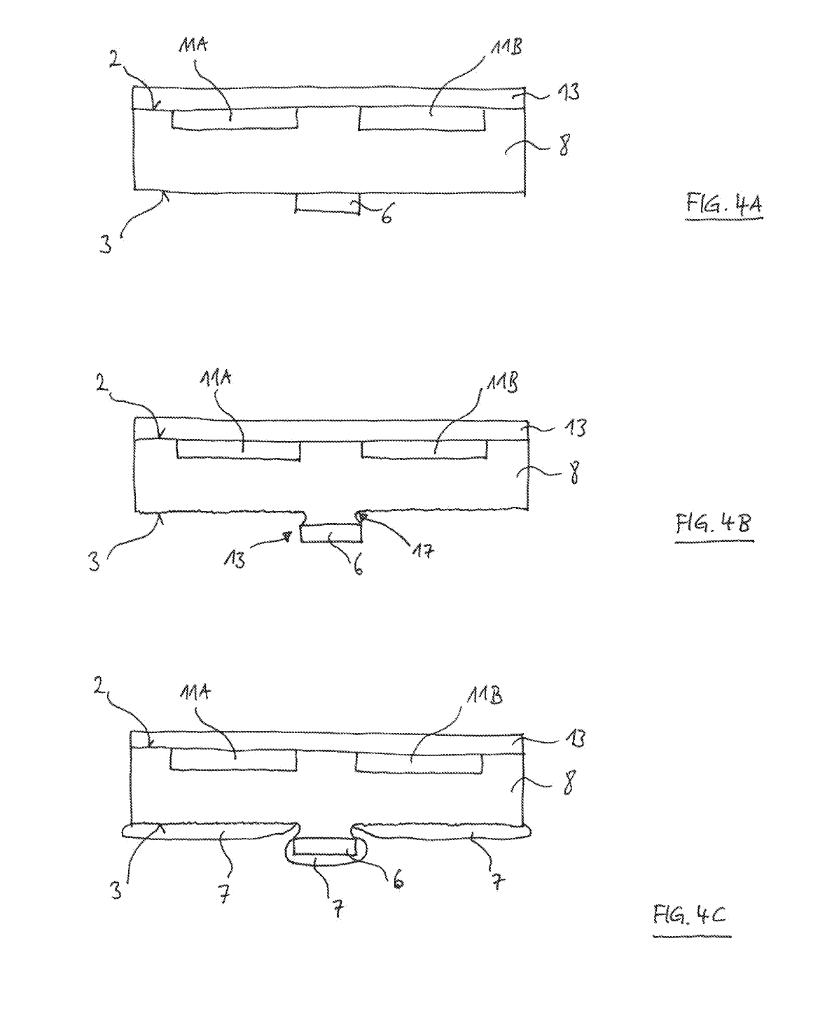

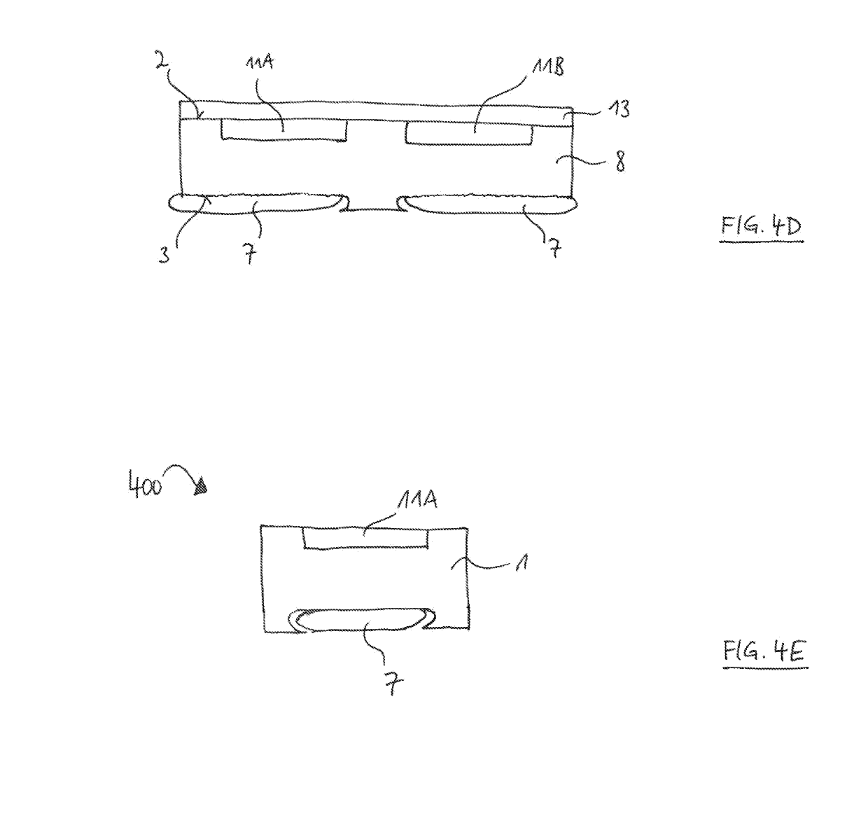

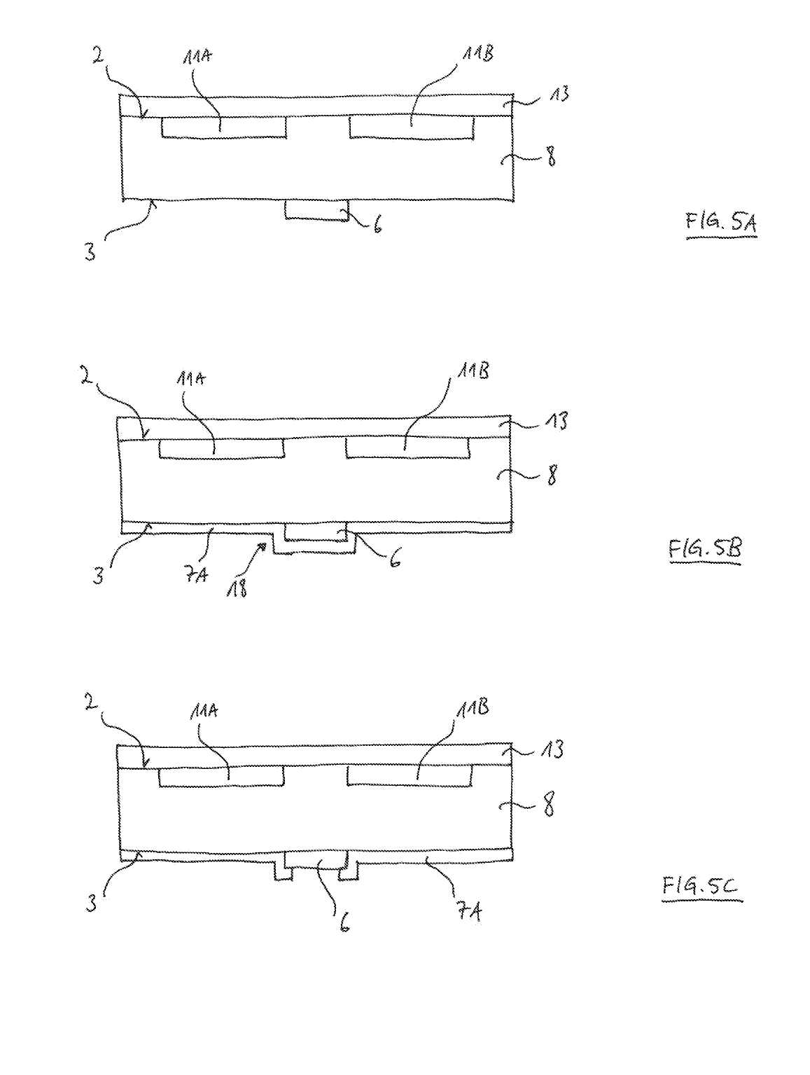

FIGS. 4A to 4E schematically illustrate a method for manufacturing a device 400 in accordance with the disclosure. The device 400 may be seen as an implementation of the device 100 of FIG. 1 and the device manufactured by the method of FIGS. 2A to 2C. In addition, the device 400 may be seen as an implementation of the devices 600 and 700 described below. Details of the device 400 manufactured by the method of FIGS. 4A to 4E may thus be likewise applied to all further devices in accordance with the disclosure. In addition, the method shown in FIGS. 4A to 4E may be seen as an implementation of the method illustrated in FIGS. 2A to 2C. Details of the manufacturing method that are described below may therefore be likewise applied to the method of FIGS. 2A to 2C.

In FIG. 4A, a device similar to FIG. 3D may be provided. Further method steps may have been performed before, for example one or more of the method steps described in connection with FIGS. 3A to 3D.

In FIG. 4B, three methods steps may be performed. First, semiconductor material of the semiconductor wafer 8 may be removed at regions not covered by the dielectric material 6. In particular, the semiconductor material may be removed to provide a rough surface of the semiconductor wafer 8. Such roughened surface may improve a deposition of material on the roughened semiconductor wafer 8, in particular a material including tantalum. Usage of an adhesive agent, an adhesive layer and the like may thus be avoided. Second, semiconductor material of the semiconductor wafer 8 may be removed underneath the dielectric material 6 such that undercuts 17 may be formed. Third, the height of the step 14 may be adjusted as it has already been described in connection with FIG. 3E. For example, the three steps may be performed by applying one or more (silicon) wet etch processes. In this case, the undercuts 17 may also be referred to as under-etch openings.

In FIG. 4C, an electrically conductive material 7 may be deposited on the backside 3 of the semiconductor wafer 8. For example, the electrically conductive material 7 may include one or more electrically conductive layers. Any suitable technique may be used for depositing the electrically conductive material 7. For example, a titanium layer may be deposited by means of at least one of a sputtering process, a vapor deposition process, etc. Further layers may be deposited on the titanium layer, wherein the further layers may support later assembly processes (e.g., diffusion soldering) and/or a layer passivation. In one example, the further layers may, e.g., include tin-silver (SnAg).

The electrically conductive material 7 may be arranged over the semiconductor wafer 8 and over the dielectric material 6 in such a way that the semiconductor wafer 8 may be exposed from the electrically conductive material 7 at the position of the undercut 17. The absence of the electrically conductive material 7 at the position of the undercut 17 may result in a predetermined breaking point that may support a step of separating the semiconductor chips later on, for example by applying the technique of FIG. 3H.

In FIG. 4D, the dielectric material 6 and the electrically conductive material 7 arranged thereon may be removed, for example by means of a diluted HF (hydrofluoric acid) wet etch process.

Further method steps (not illustrated) may be performed, for example one or more of the methods steps described in connection with FIGS. 3G to 3H.

In FIG. 4E, a separated device 400 obtained after a separation of the semiconductor wafer 8 is illustrated, wherein an undercut structure may be arranged at a peripheral region on the right and the left of the backside of the device 400, respectively.

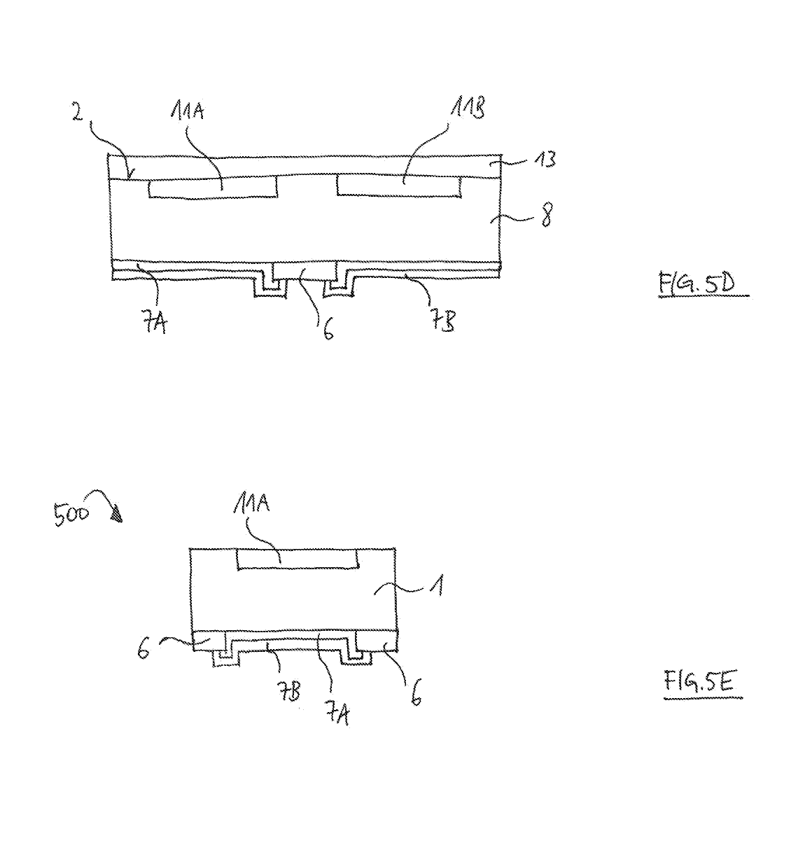

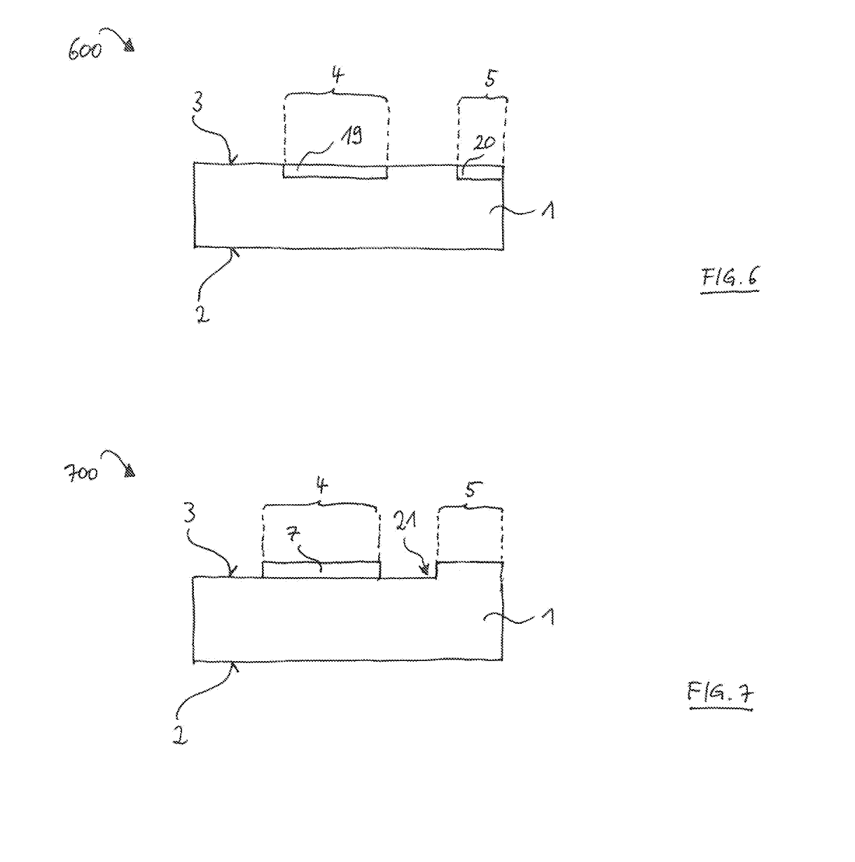

FIGS. 5A to 5E schematically illustrate a method for manufacturing a device 500 in accordance with the disclosure. The device 500 may be seen as an implementation of the device 100 of FIG. 1 and the device manufactured by the method of FIGS. 2A to 2C. In addition, the device 500 may be seen as an implementation of the devices 600 and 700 described below. Details of the device 500 may thus be likewise applied to all further devices in accordance with the disclosure. In addition, the method shown in FIGS. 5A to 5E may be seen as an implementation of the method illustrated in FIGS. 2A to 2C. Details of the manufacturing method that are described below may therefore be likewise applied to the method of FIGS. 2A to 2C.

In FIG. 5A, a device similar to FIG. 3D may be provided. Further method steps may have been performed before, for example one or more of the method steps described in connection with FIGS. 3A to 3D.

In FIG. 5B, a first electrically conductive material 7A is deposited on the backside 3 of the semiconductor wafer 8 wherein any suitable material and/or technique described above may be used. The first electrically conductive layer 7A may be used as a base layer for an electroless plating process performed later on. In one example, the first electrically conductive material 7A may, e.g., include an aluminum layer. After depositing the first electrically conductive material 7A, an elevation (or step) 18 may be formed in the first electrically conductive material 7A at the position of the dielectric material 6 arranged underneath.

In FIG. 5C, the first electrically conductor material 7A may be patterned, for example by means of a lithographic process. The first electrically conductive material 7A may be opened at the positions of the dielectric material 6 such that that the dielectric material 6 may at least partly be exposed. The elevation 18 and/or the exposure of the dielectric material 6 may be used as an identification mark for aligning a lithography mask on the non-transparent backside of the semiconductor wafer 8. For example, such alignment may be helpful when an alignment based on an infrared analysis and performed from the frontside 2 of the semiconductor wafer 8 is not possible, since the carrier 13 is not transparent for infrared radiation.

In FIG. 5D, a second electrically conductive material 7B may be deposited over the first electrically conductive material 7A wherein any suitable material and/or technique described before may be used. For example, the second electrically conductive material 7B may be copper-based or nickel-based and may be deposited by means of an electroless plating process. After depositing the second electrically conductive material 7B, at least a part of the dielectric material 6 may remain exposed. In FIG. 5D, a surface of the dielectric material 6 facing away from the semiconductor wafer 8 and a surface of the electrically conductive materials 7a, 7B facing away from the semiconductor chip may have different levels. By applying the second electrically conductive material 7B, a sidewall passivation of sensitive layers (e.g., made of copper) may be achieved such that a risk of a copper-silicon (CuSi) formation may be avoided.

In FIG. 5E, a separated device 500 obtained after a separation of the semiconductor wafer 8 is illustrated, wherein the dielectric material 6 may be arranged over a peripheral region on the right and the left of the backside of the device 500, respectively.

FIG. 6 schematically illustrates a cross-sectional view of a device 600 in accordance with the disclosure. The device 600 includes a semiconductor chip 1 including a first main face 2 and a second main face 3 wherein the second main face 3 is the backside of the semiconductor chip 1. The second main face 3 includes a first region 4 and a second region 5, wherein the second region 5 is a peripheral region of the second main face 3. A material structure 19 of the semiconductor chip 1 at the first region 4 differs from a material structure 20 of the semiconductor chip 1 at the second region 5. The device 600 of FIG. 6 is similar to the devices manufactured by previously described methods. Comments made in connection with foregoing figures may thus also hold true for the device 600.

FIG. 7 schematically illustrates a cross-sectional view of a device 700 in accordance with the disclosure. The device 700 includes a semiconductor chip 1 including a first main face 2 and a second main face 3, wherein the second main face 3 is the backside of the semiconductor chip 1. The second main face 3 includes a first region 4 and a second region 5, wherein the second region 5 is a peripheral region of the second main face 3. A level of the first region 4 is different from a level of the second region 5. In FIG. 7, the different levels are indicated by a step 21. However, it is understood that a difference and/or a transition between the levels of the regions may be of arbitrary form or shape. The device 700 further includes an electrically conductive material 7 arranged over the first region 4. The device 700 of FIG. 7 is similar to the devices manufactured by previously described methods. Comments made in connection with the foregoing figures may thus also hold true for the device 700.

While a particular feature or aspect of the invention may have been disclosed with respect to only one of several implementations, such feature or aspect may be combined with one or more other features or aspects of the other implementations as may be desired and advantageous for any given or particular application. Furthermore, to the extent that the terms “include,” “have,” “with” or other variants thereof are used in either the detailed description or the claims, such terms are intended to be inclusive in a manner similar to the term “comprise.” Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

Although specific embodiments have been illustrated and described herein, it will be appreciated by those of ordinary skill in the art that a variety of alternate and/or equivalent implementations may be substituted for the specific aspects shown and described without departing from the scope of the present invention. This application is intended to cover any adaptations or variations of the specific aspects discussed herein. Therefore, it is intended that this invention be limited only by the claims and the equivalents thereof.

What is claimed is:

1. A device, comprising:
a semiconductor chip comprising a first main face and a second main face, the second main face being a backside of the semiconductor chip, wherein the second main face comprises a first region and a second region, the second region being a peripheral region of the second main face;
a dielectric material arranged over the second region; and
an electrically conductive material arranged over the first region.

2. The device of claim 1, wherein the first main face comprises at least one of a doped region, an electrical component, and an integrated circuit.

3. The device of claim 1, wherein the first region has an area that is at least 80 percent of an overall area of the second main face.

4. The device of claim 1, wherein a level of the semiconductor chip at the first region is different from a level of the semiconductor chip at the second region.

5. The device of claim 1, wherein a surface of the dielectric material facing away from the semiconductor chip and a surface of the electrically conductive material facing away from the semiconductor chip are arranged in a common plane.

6. The device of claim 1, wherein a surface of the dielectric material facing away from the semiconductor chip and a surface of the electrically conductive material facing away from the semiconductor chip have different levels.

7. The device of claim 1, further comprising an undercut arranged under the second region.

8. The device of claim 1, wherein the dielectric material comprises a polymer, a nitride, an oxide, or a low temperature oxide.

9. The device of claim 1, wherein the dielectric material comprises a stripe having a width between 10 micrometers and 30 micrometers.

10. The device of claim 1, wherein the electrically conductive material comprises a metal paste.

11. The device of claim 1, wherein the electrically conductive material comprises a stack of multiple electrically conductive layers.

12. The device of claim 1, wherein the semiconductor chip comprises a power semiconductor chip and the electrically conductive material is electrically coupled to an electrode of the power semiconductor chip.

13. A device, comprising:
a semiconductor chip comprising a first main face and a second main face;
wherein the second main face is a backside of the semiconductor chip;
wherein the second main face comprises a first region and a second region, the second region being a peripheral region of the second main face; and
wherein a material structure of the semiconductor chip at the first region differs from a material structure of the semiconductor chip at the second region.

14. The device of claim 13, wherein the material structure of the semiconductor chip at the first region comprises a first crystalline structure and the material structure of the semiconductor chip at the second region comprises a second crystalline structure different from the first crystalline structure.

15. The device of claim 13, wherein the material structure of the semiconductor chip at the first region is substantially monocrystalline and the material structure of the semiconductor chip at the second region is substantially polycrystalline.

16. The device of claim 13, further comprising an electrically conductive material arranged over the first region.

17. A device, comprising:
a semiconductor chip comprising a first main face and a second main face, the second main face being a backside of the semiconductor chip, wherein the second main face comprises a first region and a second region, the second region being a peripheral region of the second main face, and wherein a level of the first region is different from a level of the second region; and
an electrically conductive material arranged over the first region.

18. A method, comprising:
providing a semiconductor wafer comprising a first main face and a second main face, wherein the second main face is a backside of the semiconductor wafer;
laser dicing the semiconductor wafer; and
after laser dicing the semiconductor wafer, arranging an electrically conductive material over the second main face.

19. The method of claim 18, wherein
the first main face comprises a first die, a second die, and a peripheral region arranged between the first die and the second die,
the second main face comprises a first region arranged opposite to the first die and the second die, and a second region arranged opposite to the peripheral region, and
the electrically conductive material is arranged over the first region.

20. The method of claim 19, further comprising, before arranging the electrically conductive material, arranging a dielectric material over the first region and the second region.

21. The method of claim 20, further comprising increasing a density of the dielectric material over the second region.

22. The method of claim 21, wherein increasing the density of the dielectric material over the second region comprises processing the dielectric material over the second region using laser radiation.

23. The method of claim 21, further comprising removing the dielectric material having increased density over the first region.

24. The method of claim 20, wherein the electrically conductive material is arranged over the first region such that a surface of the dielectric material facing away from the semiconductor wafer and a surface of the electrically conductive material facing away from the semiconductor wafer are arranged in a common plane.

25. The method of claim 20, further comprising, before arranging the electrically conductive material, removing semiconductor material of the semiconductor wafer such that an undercut is formed under the second region.

26. The method of claim 25, wherein the electrically conductive material is arranged over the first region and over the second region such that the semiconductor wafer is exposed from the electrically conductive material at the position of the undercut.

27. The method of claim 18, wherein arranging the electrically conductive material comprises arranging a metal paste by squeegeeing, printing, dispensing, laminating, or spin-coating.

28. The method of claim 18, further comprising patterning the electrically conductive material.

29. The method of claim 28, further comprising depositing a further electrically conductive material over the patterned electrically conductive material.
